(19) United States
(12) Patent Application Publication
(10) Pub. No.: US 2016/0021736 A1
(43) Pub. Date: Jan. 21, 2016

(54) PRINTED CIRCUIT BOARD AND METHOD OF MANUFACTURING THE SAME

(71) Applicant: Samsung Electro-Mechanics Co., Ltd., Suwon-si (KR)

(72) Inventors: Gi Ho HAN, Suwon-Si (KR); Gun Woo KIM, Suwon-Si (KR); Sung Won JEONG, Suwon-Si (KR); Ki Hwan KIM, Suwon-Si (KR); Da Hee KIM, Suwon-Si (KR); Yong Yoon CHO, Suwon-Si (KR)

(73) Assignee: Samsung Electro-Mechanics Co., Ltd., Suwon-si (KR)

(21) Appl. No.: 14/804,442

(22) Filed: Jul. 21, 2015

(30) Foreign Application Priority Data
Jul. 21, 2014 (KR) 10-2014-0091853

(51) Int. Cl. H05K 1/02; H05K 3/46; H05K 3/40; H05K 1/11; H05K 3/00

(52) U.S. Cl. CPC H05K 1/0271; H05K 1/113; H05K 3/007; H05K 3/4038; H05K 3/0044; H05K 3/4644; H05K 2201/096; H05K 2201/09563

(57) ABSTRACT

There are provided a printed circuit board and a method of manufacturing the same. The printed circuit board according to an exemplary embodiment of the present disclosure includes: a first insulating layer; a second insulating layer formed below the first insulating layer; a via pad formed on an upper surface of the second insulating layer and formed so as to be buried in the second insulating layer; a double via formed on an upper surface of the via pad, formed so as to penetrate through the first insulating layer, and including an auxiliary via and a first via; and a second via formed on a lower surface of the via pad and formed so as to penetrate through the second insulating layer.

### CROSS-REFERENCE TO RELATED APPLICATION

This application claims the benefit of Korean Patent Application No. 10-2014-0091853, filed on Jul. 21, 2014, entitled “Printed Circuit Board and Method of Manufacturing the Same” which is hereby incorporated by reference in its entirety into this application.

### BACKGROUND

The present disclosure relates to a printed circuit board and a method of manufacturing the same.

Recently, a trend toward multi-functionalization and a speed increase of electronic products has been rapidly progressed. In accordance with this trend, a semiconductor chip and a printed circuit board on which the semiconductor chip is mounted have also been rapidly developed. In the printed circuit board as described above, thinness and lightness, fine circuit implementation, excellent electrical characteristics, high reliability, a high speed signal transfer, and the like, are demanded. In accordance with thinness and lightness of the printed circuit board, a warpage phenomenon occurs. According to the related art, in order to prevent the warpage phenomenon of the printed circuit board, a core substrate having a core layer inserted thereinto has been mainly used.

### RELATED ART DOCUMENT

### Patent Document

(Patent Document 1) US Patent Application Publication No. 20040058136

### SUMMARY

An aspect of the present disclosure may provide a printed circuit board capable of decreasing warpage due to a difference in the amount of polishing of upper and lower parts, and a method of manufacturing the same.

According to an aspect of the present disclosure, a printed circuit board may include: a first insulating layer; a second insulating layer formed below the first insulating layer; a via pad formed on an upper surface of the second insulating layer and formed so as to be buried in the second insulating layer; a double via formed on an upper surface of the via pad, formed so as to penetrate through the first insulating layer, and including an auxiliary via and a first via; and a second via formed on a lower surface of the via pad and formed so as to penetrate through the second insulating layer.

According to another aspect of the present disclosure, a method of manufacturing a printed circuit board may include: forming a double via including an auxiliary via and a first via on a carrier substrate; forming a first insulating layer formed on the carrier substrate so as to bury the double via; removing the carrier substrate; forming a via pad on a lower surface of the auxiliary via; forming a second via below the via pad; and forming a second insulating layer formed below the first insulating layer so as to bury the second via and the via pad.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is an illustrative diagram showing a printed circuit board according to an exemplary embodiment of the present disclosure; and

FIGS. 2 through 15 are illustrative diagrams showing a method of manufacturing a printed circuit board according to an exemplary embodiment of the present disclosure.

### DETAILED DESCRIPTION

The objects, features and advantages of the present disclosure will be more clearly understood from the following detailed description of the exemplary embodiments taken in conjunction with the accompanying drawings. Throughout the accompanying drawings, the same reference numerals are used to designate the same or similar components, and redundant descriptions thereof are omitted. Further, in the following description, the terms “first,” “second,” “one side,” “the other side” and the like are used to differentiate a certain component from other components, but the configuration of such components should not be construed to be limited by the terms. Further, in the description of the present disclosure, when it is determined that the detailed description of the related art would obscure the gist of the present disclosure, the description thereof will be omitted.

Hereinafter, exemplary embodiments of the present disclosure will be described in detail with reference to the accompanying drawings.

FIG. 1 is an illustrative diagram showing a printed circuit board according to an exemplary embodiment of the present disclosure.

For convenience of description and understand for exemplary embodiments of the present disclosure, on the basis of FIG. 1, one direction is defined as an upward direction and the other direction is defined as a downward direction.

Referring to FIG. 1, a printed circuit board 100 according to an exemplary embodiment of the present disclosure includes a first insulating layer 121, a second insulating layer 122, a double via 110, a second via 142, a first via pad 131, a build-up insulating layer 125, a build-up via 145, a build-up via pad 135, a first circuit pattern 151, and a second circuit pattern 152.

According to an exemplary embodiment of the present disclosure, the first insulating layer 121 and the second insulating layer 122 are made of a complex polymer resin which is typically used as an interlayer insulating material. For example, the first insulating layer 121 and the second insulating layer 122 are made of prepreg, Ajinomoto Build up Film (ABF), and an epoxy based resin such as FR-4, Bismaleimide Triazine (BT), or the like.

According to an exemplary embodiment of the present disclosure, the second insulating layer 122 is formed below the first insulating layer 121.

According to an exemplary embodiment of the present disclosure, the double via 110 is formed in the first insulating layer 121. In addition, the double via 110 is formed so as to penetrate through the first insulating layer 121. Here, the double via 110 includes an auxiliary via 111 and a first via 112.

According to an exemplary embodiment of the present disclosure, the auxiliary via 111 is formed on the first via pad 131 formed in the second insulating layer 122. That is, a lower surface of the auxiliary via 111 is formed so as to be in contact with an upper surface of the first via pad 131. In addition, the first via 112 is formed on an upper surface of the auxiliary via 111.

As shown in FIG. 1, the auxiliary via 111 and the first via 112 are formed so as to have diameters different from each other. That is, a structure in which the auxiliary via 111 has the diameter larger than that of the first via 112 is shown in FIG. 1. However, the structure in which the auxiliary via 111 has the diameter larger than that of the first via 112 is merely an illustrative example, and is not limited as a structure of the auxiliary via 111 and the first via 112. The auxiliary via 111 and the first via 112 may have the same diameter as each other or different diameters.

According to an exemplary embodiment of the present disclosure, the first via 112 and the auxiliary via 111 are made of a conductive material used in the field of circuit board. In addition, the auxiliary via 111 and the first via 112 may be made of the different materials and may be made of the same material as each other. For example, the first via 112 and the auxiliary via 111 are made of copper.

According to an exemplary embodiment of the present disclosure, the first via pad 131 is formed on an upper surface of the second insulating layer 122 so as to be buried in the second insulating layer 122. An upper surface of the first via pad 131 is bonded to the auxiliary via 111 and a lower surface thereof is bonded to the second via 142. The first via pad 131 according to an exemplary embodiment of the present disclosure is made of a conductive material used in a field of circuit board. For example, the first via pad 131 is made of copper.

According to an exemplary embodiment of the present disclosure, the second via 142 is formed on the lower surface of the first via pad 131 so as to penetrate through the second insulating layer 122. The second via 142 according to an exemplary embodiment of the present disclosure is made of a conductive material used in a field of circuit board. For example, the second via 142 is made of copper.

According to an exemplary embodiment of the present disclosure, the build-up insulating layer 125 is formed on the first insulating layer 121. The build-up insulating layer 125 according to an exemplary embodiment of the present disclosure includes a third insulating layer 123 and a fourth insulating layer 124. The third insulating layer 123 is formed on the first insulating layer 121 and the fourth insulating layer 124 is formed on the third insulating layer 123.

According to an exemplary embodiment of the present disclosure, the third insulating layer 123 and the fourth insulating layer 124 are made of a complex polymer resin which is typically used as an interlayer insulating material. For example, the third insulating layer 123 and the fourth insulating layer 124 are made of prepreg, Ajinomoto Build up Film (ABF), and an epoxy based resin such as FR-4, Bismaleimide Triazine (BT), or the like.

According to an exemplary embodiment of the present disclosure, the build-up via pad 135 includes a second via pad 132 and a third via pad 133. The second via pad 132 is formed on a lower surface of the third insulating layer 123 so as to be buried in the third insulating layer 123. A lower surface of the second via pad 132 is bonded to the first via 112. In addition, the third via pad 133 is formed on a lower surface of the fourth insulating layer 124 so as to be buried in the fourth insulating layer 124. The second via pad 132 and the third via pad 133 according to an exemplary embodiment of the present disclosure are made of a conductive material used in the field of circuit board. For example, the second via pad 132 and the third via pad 133 are made of copper.

According to an exemplary embodiment of the present disclosure, the build-up via 145 includes a third via 143 and a fourth via 144. The third via 143 is formed on an upper surface of the second via pad 132 so as to penetrate through the third insulating layer 123. In addition, the fourth via 144 is formed on an upper surface of the third via pad 133 so as to penetrate through the fourth insulating layer 124. The third via 143 and the fourth via 144 according to an exemplary embodiment of the present disclosure are made of a conductive material used in the field of circuit board. For example, the third via 143 and the fourth via 144 are made of copper.

According to an exemplary embodiment of the present disclosure, the auxiliary via 111 instead of the via pad is formed in the insulating layer 121. In addition, the first via pad 131 having a structure that it protrudes from the first insulating layer 121 is formed. In addition, the second via pad 132 and the third via pad 133 formed on the first insulating layer 121 are also formed in a structure that they protrude from the first insulating layer 121.

By the structure as described above, the insulating layers formed at the outermost portion may be formed so as to have the same thickness as each other. That is, when the second via 142 and the fourth via 144 have the same thickness, the second insulating layer 122 and the fourth insulating layer 124 also have the same thickness as each other. Therefore, the second insulating layer 122 and the fourth insulating layer 124 have the same insulating distance.

Although an exemplary embodiment of the present disclosure describes the structure in which four insulating layers are formed, by way of example, the present disclosure is not limited to the above-mentioned structure. For example, the printed circuit board 100 according to an exemplary embodiment of the present disclosure may have a structure in which the build-up insulating layer 125, the build-up via pad 135, and the build-up via 145 are omitted. In this case, the insulating layers at the outermost layer of the printed circuit layer 100 are the first insulating layer 121 and the second insulating layer 122. Therefore, the first insulating layer 122 and the second insulating layer 124 are formed so as to have the same thickness as each other. In addition, the double via 110 has the same thickness as a summation of thicknesses of the first via pad 131 and the second via 142.

According to an exemplary embodiment of the present disclosure, the first circuit pattern 151 is formed on the fourth insulating layer 124 so as to be bonded to the fourth via 144. In addition, the second circuit pattern 152 may be formed below the second insulating layer 122 so as to be boned to the second via 142. The first circuit pattern 151 and the second circuit patter 152 according to an exemplary embodiment of the present disclosure are made of a conductive material used in the field of circuit board. For example, the first circuit pattern 151 and the second circuit pattern 152 are made of copper.

Although not shown in FIG. 1, the first circuit pattern 151 and the second circuit pattern 152 may have surface treatment layers formed on surfaces thereof. The surface treatment layer prevents the first circuit pattern 151 and the second circuit pattern 152 from being damaged due to oxidation and corrosion thereof.

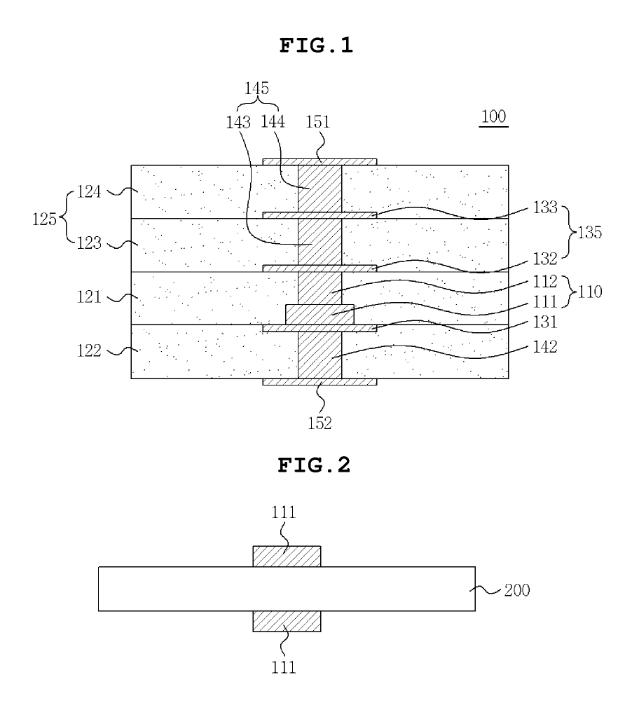

FIGS. 2 through 15 are illustrative diagrams showing a method of manufacturing a printed circuit board according to an exemplary embodiment of the present disclosure.

FIGS. 2 through 15 are examples of a method of manufacturing the printed circuit board (100 in FIG. 1).

Referring to FIG. 2, the auxiliary via 111 is formed on a carrier substrate 200.

According to an exemplary embodiment of the present disclosure, the carrier substrate 200 is to support the circuit pattern, the insulating layer, and the like when forming the circuit pattern, the insulating layer, and the like. The carrier substrate 200 may be made of an insulating material or a metal material. In addition, the carrier substrate 200 may have a laminate structure in which a metal member is formed on one surface or both surfaces of an insulating member. In this case, the carrier substrate 200 may further include a releasing material formed between the insulating member and a metal member in order to more easily separate the carrier substrate 200 from a printed circuit board (not shown) to be formed later.

According to an exemplary embodiment of the present disclosure, the auxiliary via 111 is each formed on a top and a bottom of the carrier substrate 200. The auxiliary via 111 according to an exemplary embodiment of the present disclosure may be formed by any method of various methods of forming the via in the field of circuit board. For example, a seed layer (not shown) is formed on the carrier substrate 200 and a plating resist (not shown) including an opening part is formed thereon. Next, the auxiliary via 111 may be formed by a method of performing a plating for the opening part and removing the plating resist and the seed layer exposed to the outside. Alternatively, the plating is performed on the top of the carrier substrate 200 and an etching resist (not shown) having the opening part is formed thereon. Next, the auxiliary via 111 may be formed by a method of etching the plating exposed by the etching resist and removing the etching resist. The above-mentioned method of forming the auxiliary via 111 according to an exemplary embodiment of the present disclosure is merely an illustrative example and the present invention is not limited thereto.

In addition, the auxiliary via 111 is made of a conductive material used in a field of circuit board. For example, the auxiliary via 111 is made of copper.

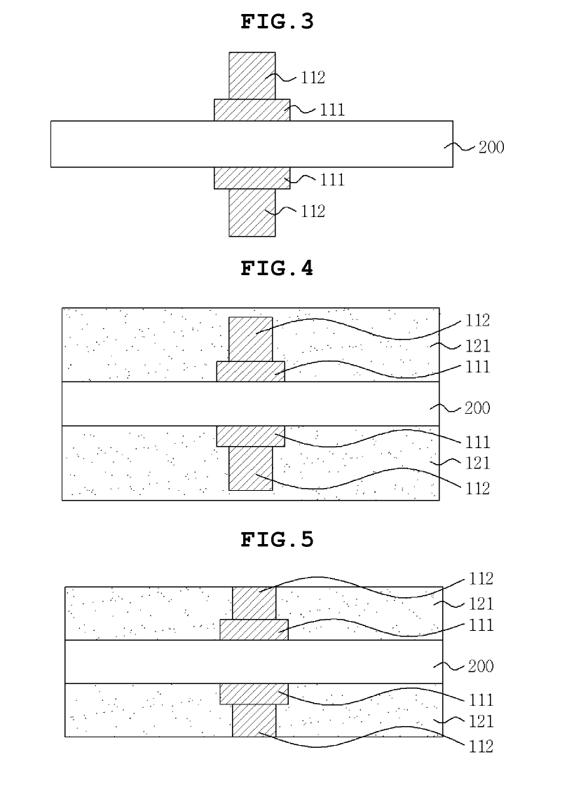

Referring to FIG. 3, the first via 112 is formed.

According to an exemplary embodiment of the present disclosure, the first via 112 is formed on the auxiliary via 111. FIG. 3 shows that the first via 112 is formed so as to have a diameter smaller than that of the auxiliary via 111. However, the diameters of the first via 112 and the auxiliary via 111 are not always different. The first via 112 and the auxiliary via 111 may be formed so as to have the same diameter as each other and may also be formed so as to the diameters different from each other.

The first via 112 according to an exemplary embodiment of the present disclosure may be formed by any method of methods of forming the via in the field of circuit board. For example, the first via 112 is formed by one of tenting, SAP or MASP method. In addition, the first via 112 is made of a conductive material used in a field of circuit board. For example, the first via 112 is made of copper.

Referring to FIG. 4, a first insulating layer 121 is formed.

According to an exemplary embodiment of the present disclosure, the first insulating layer 121 is formed by stacking and pressing an insulating material of a film type on the carrier substrate 200. The first insulating layer 121 formed as described above is formed on the carrier substrate 200 so as to bury the auxiliary via 111 and the first via 112. In this case, as shown in FIG. 4, the first insulating layer 121 may be formed so as to cover an upper surface of the first via 112.

The first insulating layer 121 according to an exemplary embodiment of the present disclosure may be made of a complex polymer resin which is typically used as an interlayer insulating material. For example, the first insulating layer 121 is made of a prepreg, Ajinomoto Build up Film (ABF), and an epoxy based resin such as FR-4, Bismaleimide Triazine (BT), or the like.

Although the exemplary embodiment of the present disclosure describes the case in which the first insulting layer 121 is made of the insulating material of the film type, by way of example, the shape of the first insulating layer 121 and a method of forming the same are not limited thereto. For example, the first insulating layer 121 may also be formed by applying an insulating material of a liquid type on the carrier substrate 200.

Referring to FIG. 5, a first insulating layer 121 is polished.

According to an exemplary embodiment of the present disclosure, a polishing process is performed for the first insulating layer 121 so that the upper surface of the first via 112 is exposed to the outside. When the first insulating layer 121 is polished, an upper portion of the first via 112 may be polished at the same time. By the polishing process as described above, the first insulating layer 121 and the first via 112 may be planarized.

According to an exemplary embodiment of the present disclosure, the polishing process may be performed by any method capable of polishing the first insulating layer 121 and the first via 112 among methods known in a field of circuit board.

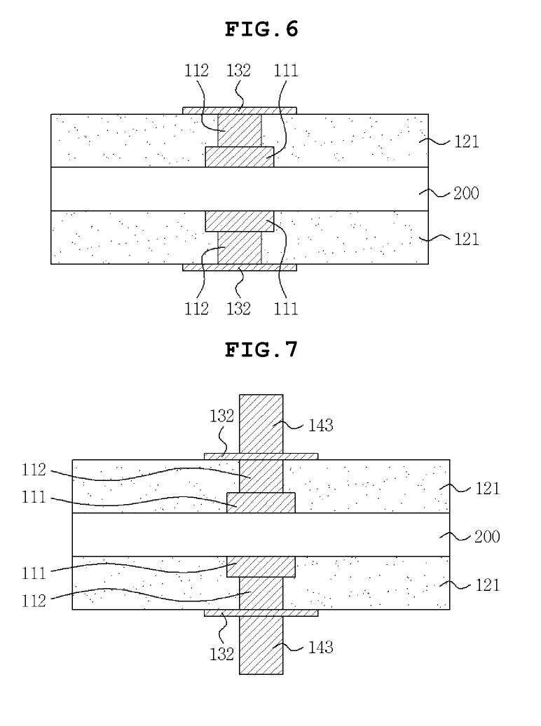

Referring to FIG. 6, the second via pad 132 is formed.

According to an exemplary embodiment of the present disclosure, the second via pad 132 is formed on the first insulating layer 121. In addition, the second via pad 132 is bonded to the first via 112.

The second via pad 132 according to an exemplary embodiment of the present disclosure may be formed by any method of methods of forming a circuit pattern known in the field of circuit board. For example, the second via pad 132 is formed by one of tenting, SAP or MASP method. In addition, the second via pad 132 is made of a conductive material used in a field of circuit board. For example, the second via pad 132 is made of copper.

Referring to FIG. 7, the third via 143 is formed.

According to an exemplary embodiment of the present disclosure, the third via 143 is formed on the second via pad 132 so as to be bonded to the second via pad 132.

The third via 143 according to an exemplary embodiment of the present disclosure may be formed by any method of methods of forming the via known in the field of circuit board. In addition, the third via 143 is made of a conductive material used in a field of circuit board such as copper. For example, the third via 143 is formed by the same method and material as the first via 112.

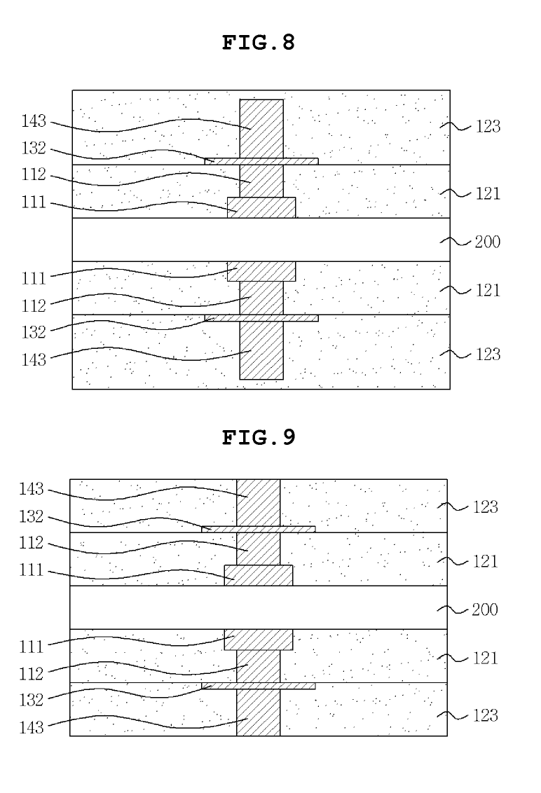

Referring to FIG. 8, the third insulating layer 123 is formed.

According to an exemplary embodiment of the present disclosure, the third insulating layer 123 is formed by stacking and pressing an insulating material of a film type on the first insulating layer 121. The third insulating layer 123 formed as described above is formed on the first insulating layer 121 so as to bury the second via pad 132 and the third via 143. In this case, as shown in FIG. 8, the third insulating layer 123 may be formed so as to cover an upper surface of the third via 143.

The third insulating layer 123 according to an exemplary embodiment of the present disclosure may be made of a complex polymer resin which is typically used as an interlayer insulating material. For example, the third insulating layer 123 is made of a prepreg, Ajinomoto Build up Film (ABF), and an epoxy based resin such as FR-4, Bismaleimide Triazine (BT), or the like.

Although the exemplary embodiment of the present disclosure describes the case in which the third insulting layer 123 is made of the insulating material of the film type, by way of example, the shape of the third insulating layer 123 and a method of forming the same are not limited thereto.

Referring to FIG. 9, the third insulating layer 123 is polished.

According to an exemplary embodiment of the present disclosure, a polishing process is performed for the third insulating layer 123 so that the upper surface of the third via 143 is exposed. When the third insulating layer 123 is polished, an upper portion of the third via 143 may be polished at the same time. By the polishing process as described above, the third insulating layer 123 and the third via 143 may be planarized.

According to an exemplary embodiment of the present disclosure, the polishing process may be performed by any method capable of polishing the third insulating layer 123 and the third via 143 among methods known in a field of circuit board.

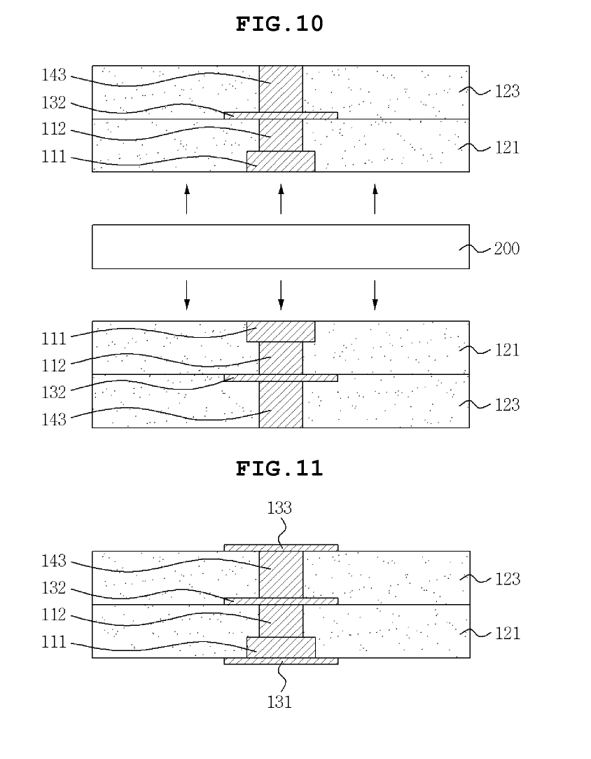

Referring to FIG. 10, the carrier substrate 200 is removed.

According to an exemplary embodiment of the present disclosure, the carrier substrate 200 and the respective first insulating layers 121 formed on both sides of the carrier substrate 200 are separated from each other.

In next processes, only one of the two separated substrates is shown and described. Although only one substrate separated from the carrier substrate 200 is shown and described in an exemplary embodiment of the present disclosure, it is apparent that the same subsequent processes are applied to the other substrate which is not shown.

Referring to FIG. 11, the first via pad 131 and the third via pad 133 are formed.

According to an exemplary embodiment of the present disclosure, the first via pad 131 is formed below the first insulating layer 121. The first via pad 131 is bonded to the auxiliary via 111.

In addition, according to an exemplary embodiment of the present disclosure, the third via pad 133 is formed on the third insulating layer 123. The third via pad 133 is bonded to the third via 143.

The first via pad 131 and the third via pad 133 according to an exemplary embodiment of the present disclosure may be formed by any method of methods of forming a circuit pattern known in the field of circuit board. For example, the first via pad 131 and the third via pad 133 may be formed by one of tenting, SAP, and MASP method. The first via pad 131 and the third via pad 133 are made of a conductive material used in the field of circuit board. For example, the first via pad 131 and the third via pad 133 are made of copper.

According to an exemplary embodiment of the present disclosure, the first via pad 131 and the third via pad 133 are simultaneously formed by the same process. Therefore, the first via pad 131 and the third via pad 133 are formed so as to have the same thickness as each other.

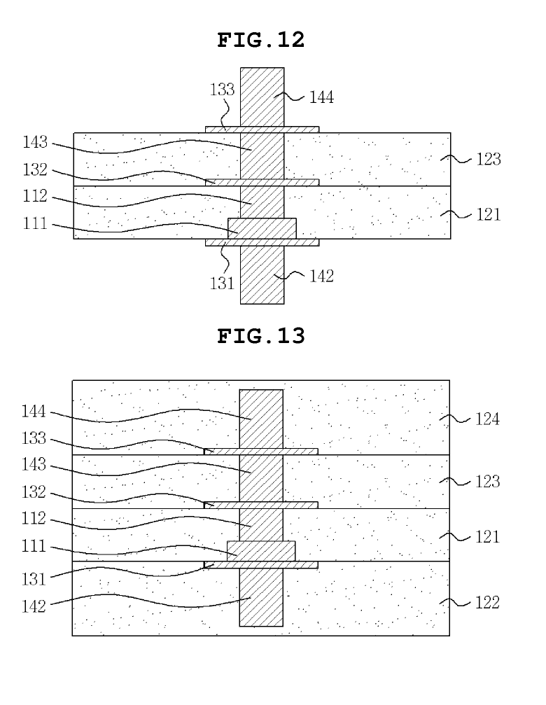

Referring to FIG. 12, the second via 142 and the fourth via 144 are formed.

According to an exemplary embodiment of the present disclosure, the second via 142 is formed below the first via pad 131. In addition, the fourth via 144 is formed on the third via pad 133.

The second via 142 and the fourth via 144 according to an exemplary embodiment of the present disclosure may be formed by any method of methods of forming the via known in the field of circuit board. In addition, the second via 142 and the fourth via 144 are made of a conductive material used in a field of circuit board such as copper. For example, the second via 142 and the fourth via 144 are formed by the same method and material as the first via 112.

According to an exemplary embodiment of the present disclosure, the second via 142 and the fourth via 144 are simultaneously formed by the same process. Therefore, the second via 142 and the fourth via 144 are formed so as to have the same thickness as each other.

Referring to FIG. 13, the second insulating layer 122 and the fourth insulating layer 124 are formed.

According to an exemplary embodiment of the present disclosure, the second insulating layer 122 is formed by stacking and pressing an insulating material of a film type below the first insulating layer 121. The second insulating layer 122 formed as described above is formed so as to bury the first via pad 131 and the second via 142.

In addition, according to an exemplary embodiment of the present disclosure, the fourth insulating layer 124 is formed by stacking and pressing an insulating material of a film type on the third insulating layer 123. The fourth insulating layer 124 formed as described above is formed so as to bury the third via pad 133 and the fourth via 144.

The second insulating layer 122 and the fourth insulating layer 124 according to an exemplary embodiment of the present disclosure may be made of a complex polymer resin which is typically used as an interlayer insulating material. For example, the second insulating layer 122 and the fourth insulating layer 124 are made of prepreg, Ajinomoto Build up Film (ABF), and an epoxy based resin such as FR-4, Bismaleimide Triazine (BT), or the like.

Although the exemplary embodiment of the present disclosure describes the case in which the second insulting layer 122 and the fourth insulating layer 124 are made of the insulating material of the film type, by way of example, the shapes of the second insulating layer 122 and the fourth insulating layer 124 and a method of forming the same are not limited thereto.

According to an exemplary embodiment of the present disclosure, the second insulating layer 122 and the fourth insulating layer 124 are simultaneously formed by the same process. Therefore, the second insulating layer 122 and the fourth insulating layer 124 may have the same thickness.

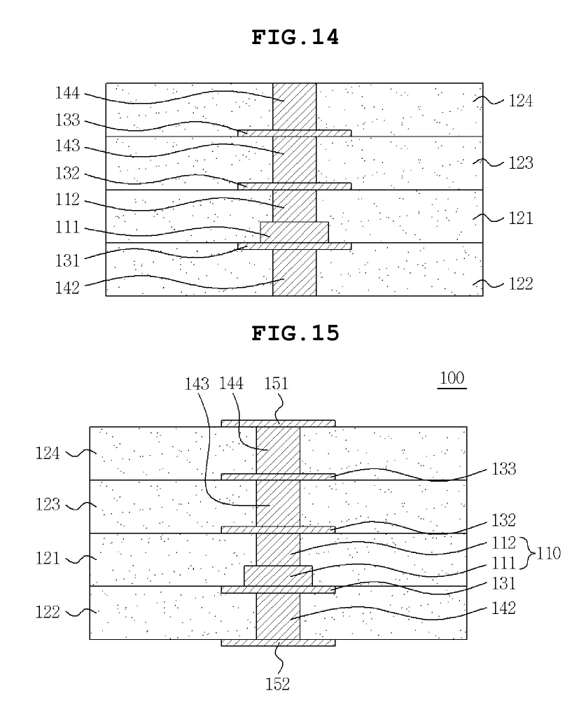

Referring to FIG. 14, the second insulating layer 122 and the fourth insulating layer 124 are polished.

According to an exemplary embodiment of the present disclosure, a polishing process is performed for the second insulating layer 122 so that the lower surface of the second via 142 is exposed. When the second insulating layer 122 is polished, a lower portion of the second via 142 may be polished at the same time. By the polishing process as described above, the second insulating layer 122 and the second via 142 are planarized.

In addition, according to an exemplary embodiment of the present disclosure, a polishing process is performed for the fourth insulating layer 124 so that the upper surface of the fourth via 144 is exposed. When the fourth insulating layer 124 is polished, an upper portion of the fourth via 144 may be polished at the same time. By the polishing process as described above, the fourth insulating layer 124 and the fourth via 144 are planarized.

According to an exemplary embodiment of the present disclosure, the polishing process may be performed by any method of polishing methods known in the field of circuit board.

According to an exemplary embodiment of the present disclosure, the second insulating layer 122 and the fourth insulating layer 124 are simultaneously polished. In addition, the second via 142 and the fourth via 144 may also be simultaneously polished. That is, according to an exemplary embodiment of the present disclosure, the second insulating layer 122 and the fourth insulating layer 124 have the same thickness and the second via 142 and the fourth via 144 also have the same thickness. Therefore, when the polishing process is performed, the second insulating layer 122 and the fourth insulating layer 124 have the same amount of polishing and the second via 142 and the fourth via 144 also have the same amount of polishing. As such, according to an exemplary embodiment of the present disclosure, by allowing the amounts of polishing of the upper portion and the lower portion to be equal to each other, warpage of the printed circuit board (100 in FIG. 1) occurring due to the polishing process may be decreased. In addition, even in the case in which the upper portion and the lower portion of the printed circuit board (100 in FIG. 1) are polished as much as the same amount (thickness), the remaining second insulating layer 122 and fourth insulating layer 124 have the same thickness. Therefore, the second insulating layer 122 and the fourth insulating layer 124, which are the outermost layers of the printed circuit board (100 in FIG. 1) may have the same insulating distance.

Although an exemplary embodiment of the present disclosure describes the structure in which four insulating layers are formed, by way of example, the present disclosure is not limited thereto. For example, according to an exemplary embodiment of the present disclosure, operation of forming a build-up insulating layer, a build-up via pad, and a build-up via may be omitted. Here, the build-up insulating layer, the build-up via pad, and the build-up via are the insulating layer, the via pad, and the via, respectively, formed on the first insulating layer 121 and the first via 112. According to an exemplary embodiment of the present disclosure, the build-up insulating layer includes the second insulating layer 123 and the fourth insulating layer 124. In addition, the build-up via pad includes the second via pad 132 and the third via pad 133. In addition, the build-up via includes the third via 143 and the fourth via 144.

As described above, in the case in which the operations of forming the build-up insulating layer, the build-up via pad, and the build-up via are omitted, the insulating layer of the outermost layer of the printed circuit board 100 becomes the first insulating layer 121 and the second insulating layer 122. Therefore, the first insulating layer 122 and the second insulating layer 124 are formed so as to have the same thickness as each other. In addition, the auxiliary via 111 and the first via 112 have the same summation of thicknesses thereof as that of the first via pad 131 and the second via 142.

Referring to FIG. 15, the first circuit pattern and the second circuit pattern 152 are formed.

According to an exemplary embodiment of the present disclosure, the first circuit pattern 151 is formed on the fourth insulating layer 124. The first circuit pattern 151 is bonded to the fourth via 144.

In addition, according to an exemplary embodiment of the present disclosure, the second circuit pattern 152 is formed below the second insulating layer 122. The second circuit pattern 152 is bonded to the second via 142.

The first circuit pattern 151 and the second circuit pattern 152 according to an exemplary embodiment of the present disclosure may be formed by any method of methods of forming a circuit pattern known in the field of circuit board. For example, the first circuit pattern 151 and the second circuit pattern 152 may be formed by one of tenting, SAP, and MASP method. The first circuit pattern 151 and the second circuit patter 152 are made of a conductive material which is used in the field of circuit board. For example, the first circuit pattern 151 and the second circuit pattern 152 are made of copper.

Although not shown in an exemplary embodiment of the present disclosure, after the first circuit pattern 151 and the second circuit pattern 152 are formed, a surface treatment layer (not shown) may be further formed. The surface treatment layer (not shown) is formed on the surfaces of the first circuit pattern 151 and the second circuit pattern 152 that are exposed to the outside.

Although the embodiments of the present disclosure have been disclosed for illustrative purposes, it will be appreciated that the present disclosure is not limited thereto, and those skilled in the art will appreciate that various modifications, additions and substitutions are possible, without departing from the scope and spirit of the disclosure.

Accordingly, any and all modifications, variations or equivalent arrangements should be considered to be within the scope of the disclosure, and the detailed scope of the disclosure will be disclosed by the accompanying claims.

What is claimed is:

1. A printed circuit board comprising:
a first insulating layer;
a second insulating layer formed below the first insulating layer;
a via pad formed on an upper surface of the second insulating layer and formed so as to be buried in the second insulating layer;
a double via formed on an upper surface of the via pad, formed so as to penetrate through the first insulating layer, and including an auxiliary via and a first via; and
a second via formed on a lower surface of the via pad and formed so as to penetrate through the second insulating layer.

2. The printed circuit board of claim 1, wherein the auxiliary via of the double via is formed on the upper surface of the via pad and the first via is formed on an upper surface of the auxiliary via.

3. The printed circuit board of claim 1, wherein the double via has the same thickness as a summation of thicknesses of the second via and the first via pad.

4. The printed circuit board of claim 1, wherein the first insulating layer and the second insulating layer have the same thickness.

5. The printed circuit board of claim 1, wherein one or more layers of a build-up insulating layer, a build-up via and a build-up via pad are further formed on the first insulating layer.

6. The printed circuit board of claim 5, wherein the second via and a first via pad have the same summation of thicknesses as that of the build-up via pad and the build-up via formed on the outermost layers.

7. A method of manufacturing a printed circuit board, the method comprising:
forming a double via including an auxiliary via and a first via on a carrier substrate;
forming a first insulating layer formed on the carrier substrate so as to bury the double via;
removing the carrier substrate;
forming a via pad on a lower surface of the auxiliary via;
forming a second via below the via pad; and
forming a second insulating layer formed below the first insulating layer so as to bury the second via and the via pad.

8. The method of claim 7, wherein in the forming of the double via, the auxiliary via is formed on an upper surface of the via pad and the first via is formed on an upper surface of the auxiliary via.

9. The method of claim 7, further comprising, after the forming of the second insulating layer, polishing the first insulating layer and the second insulating layer so as to expose the first via and the second via.

10. The method of claim 9, wherein in the polishing of the first insulating layer and the second insulating layer, the first via and the second via are polished at the same thickness.

11. The method of claim 9, wherein in the polishing of the first insulating layer and the second insulating layer, the first insulating layer and the second insulating layer are polished so as to have the same thickness as each other.

12. The method of claim 7, wherein the auxiliary via and a first via have the same summation of thicknesses as that of the via pad and the second via.

13. The method of claim 7, further comprising, before the removing of the carrier substrate, forming one or more layers of a build-up via, a build-up via pad, and a build-up insulating layer formed on the first insulating layer.

14. The method of claim 13, further comprising, after the forming of the second insulating layer, polishing the build-up insulating layer and the second insulating layer so as to expose the build-up via and the second via.

15. The method of claim 13, wherein the second via and a first via pad have the same summation of thicknesses as that of the build-up via pad and the build-up via formed on the outermost layers.
